(19) United States
(12) Patent Application Publication
(10) Pub. No.: US 2021/0332264 A1
(43) Pub. Date: Oct. 28, 2021

(54) NOVEL POLISHING VEHICLES AND COMPOSITIONS WITH TUNABLE VISCOSITY

(71) Applicant: FUJIMI CORPORATION, Tualatin, OR (US)

(72) Inventors: W. Scott Rader, Sherwood, OR (US); Shawn R. Decker, Dallas, OR (US)

(21) Appl. No.: 16/856,317

(22) Filed: Apr. 23, 2020

(51) Int. Cl. C09G 1/02; H01L 21/321

(52) U.S. Cl. CPC C09G 1/02; B24B 37/044; H01L 21/3212

(57) ABSTRACT

The present disclosure relates to aqueous polishing vehicles and polishing compositions, where the polishing compositions comprise suspended abrasive particles. More particularly, the polishing vehicles and polishing compositions have tunable viscosity, shear stability, and resistance to hard packing and thus can continuously suspend abrasive particles.

### TECHNICAL FIELD

The present disclosure relates to liquid polishing vehicles and compositions. More particularly, the polishing compositions comprising abrasive particles have tunable viscosity, shear stability, and resistance to hard packing, resulting in polishing compositions wherein the abrasive particles are continuously suspended.

### BACKGROUND

Polishing compositions comprising an abrasive (i.e., slurries or suspensions) are used for the grinding and polishing of a variety of materials and objects. These materials to be polished include hard ceramics such as silicon carbide, aluminum/titanium carbide, tungsten carbide, aluminum nitride, and alpha alumina monolith bodies. In order to polish these hard materials to a fine finish, specific polishing compositions containing abrasive agents are required. These polishing compositions typically comprise small particles that serve as an abrasive agent and a carrier medium in which the particles are contained.

One composition commonly used in polishing hard ceramic materials is a diamond polishing composition, where small diamond particles function as the abrasive. As diamond is very expensive, the polishing process itself is very costly. Other materials besides diamond, such as colloidal silica, may be used as the abrasive. While colloidal silica is cheaper than diamond, it is less effective and takes much longer to achieve an acceptable finish.

When polishing compositions comprising diamond abrasive particles are used, the diamond abrasive may be modified to impart desired polishing characteristics. For example, in order to polish a surface of silicon carbide at a high rate, the diamond abrasive will typically have a large diameter. When the diameter of the diamond abrasive is large, there is an increased and undesired tendency for the diamond abrasive to settle in the polishing composition. In order to recover the diamond abrasive from the polishing composition—a highly desired process due to the expense of diamonds—the diamond abrasive must be resuspended in the polishing composition.

In addition to a settling issue, typical polishing compositions also suffer from “shear thinning” upon use. Shear thinning is characterized by a reduction in viscosity of the carrier medium upon use of the polishing composition to polish a substrate. This reduction in viscosity leads to an increased settling of the diamond abrasive in the polishing composition.

A still further issue is that when diamond abrasive particles settle in the polishing composition, the particles may agglomerate and form what is known as a “hard pack.” In this undesired situation, the diamond particles are effectively stuck together.

The carrier vehicle imparts significant influence on flow characteristics, such as settling rates, abrasive agglomeration, and subsequent grinding and polishing performance. Additional functions of the vehicle include transporting and delivering the abrasive, maintaining the suspension of the abrasive during transport, and providing lubricating and heat management qualities that impact the performance of the abrasive. Media other than water, such as glycols, oils, or organic chemicals have been used, but these are associated with drawbacks such as high expense, toxicity, potential flammability, reactivity with the substance to be polished, and non-permanent suspension of particles.

Regardless of the vehicle used, settling out of the suspended abrasive particles is a common problem. Maintaining a suitable suspension is key in preparing a useful polishing composition. This problem has been particularly noted when using water as a medium; which, while being a common medium due to its ready availability and cheapness, produces a composition in which the abrasive particles rapidly settle out of suspension. Water-based suspensions also exhibit a relatively fast loss of moisture during use, necessitating frequent additions of fluid during polishing operations.

In light of the challenges surrounding the suspension of abrasives in polishing media, there is a need for a polishing composition that will maintain a stable viscosity range despite the conditions of use and prevent settling of the abrasive. These and other challenges are addressed by the subject matter disclosed herein.

### SUMMARY

In accordance with the purpose(s) of the currently disclosed subject matter, as embodied and broadly described herein, in one aspect relates to a polishing composition comprising a first viscosity modifying agent, a second viscosity modifying agent, a pH adjusting agent, an abrasive, and water. In an embodiment, the first viscosity modifying agent comprises a cellulose derivative or a polysaccharide, the second viscosity modifying agent comprises an anionic polymer, the pH adjusting agent comprises an inorganic or amine base, and the abrasive has an average particle size of about 50 nm or more.

In another aspect, the subject matter described herein is directed to a polishing vehicle comprising a first viscosity modifying agent, a second viscosity modifying agent, a pH adjusting agent, and water. In an embodiment, the first viscosity modifying agent comprises hydroxyethyl cellulose or xanthan gum present in an amount from about 0.5 wt % to about 5 wt %; the second viscosity modifying agent comprises a polyacrylic acid present in an amount from about 0.05 wt % to about 1 wt %; and the pH adjusting agent is selected from the group consisting of trimethylamine, diisopropanolamine, KOH, and NaOH, wherein the pH adjusting agent is present in an amount from about 0.001 to about 0.1 wt %; wherein the wt % is a wt % of the entire vehicle.

In another aspect, the subject matter described herein is directed to a method of preparing the polishing composition described herein, the method comprising the steps of mixing the first viscosity modifying agent, the second viscosity modifying agent, the pH adjusting agent, the abrasive, and water.

In another aspect, the subject matter described herein is directed to a method for polishing a substrate, the method comprising the steps of: 1) preparing the polishing composition described herein; and 2) polishing the substrate with the polishing composition.

These and other aspects are disclosed in further detail below.

### BRIEF DESCRIPTION OF THE FIGURES

FIG. 1 shows the effect of shear on several formulations. Formulation 8 suffers from a sensitivity to shear. Addition of the wetting agent (i.e., cellulose derivative) stabilized the viscosity to shear. Formulations 1, 2, and 3 show excellent shear stability.

FIG. 2 shows the settling test for Formulations 1 and 2. The settling rates trend with viscosity in that the higher the viscosity, the slower the settling rate. Post-shear viscosities for Formulations 1 (about 70 cP), 2 (about 40 cP), and Formulation 8 (about 20 cP). Pre-shear viscosity for Formulation 1 (about 80 cP).

FIG. 3 shows the soft settling of Formulations 1 and 2. Inversion and sitting for 20 minutes shows no significant hard packing after 48 hours of sitting.

FIG. 4 shows a graph of surface roughness.

FIG. 5 shows a graph of removal rates. Formulation 1 has the best combined performance in surface roughness and removal rates when accounting for shear stability.

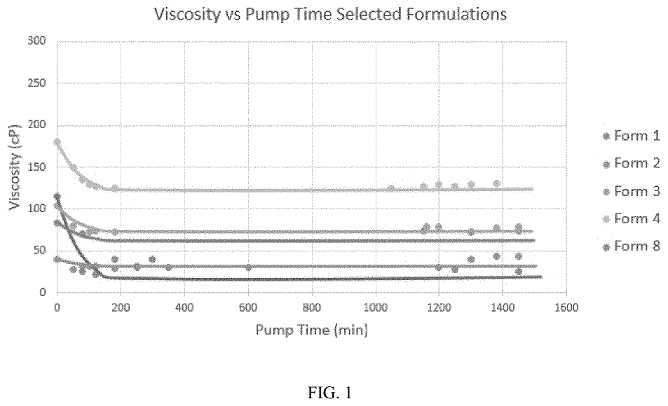

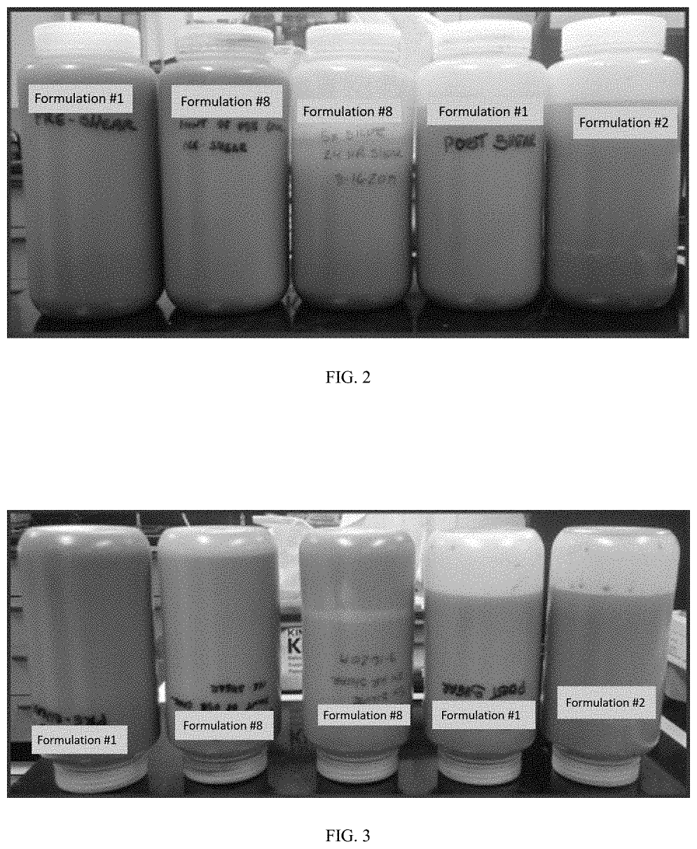

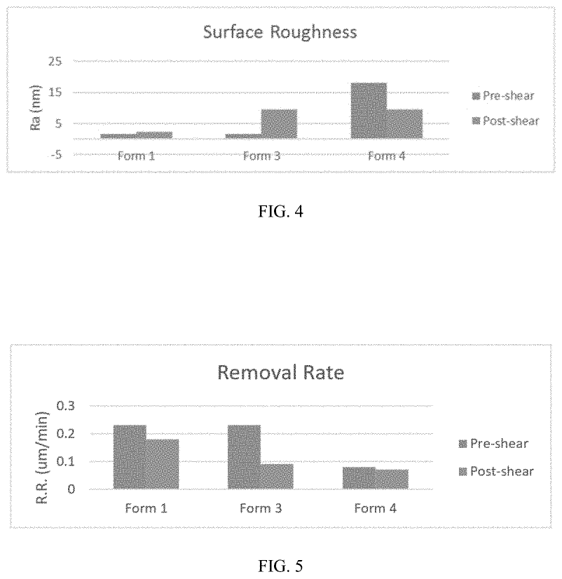

### DETAILED DESCRIPTION

The present invention can be understood more readily by reference to the following detailed description of the invention and the Examples included therein.

Before the present compounds, compositions, articles, systems, devices, and/or methods are disclosed and described, it is to be understood that they are not limited to specific synthetic methods unless otherwise specified, or to particular reagents unless otherwise specified, as such may, of course, vary. It is also to be understood that the terminology used herein is for the purpose of describing particular aspects only and is not intended to be limiting. Although any methods and materials similar or equivalent to those described herein can be used in the practice or testing of the present invention, example methods and materials are now described.

As described herein, in embodiments, are polishing compositions intended for polishing a substrate where the polishing compositions exhibit at least one benefit such as: 1) prevention of abrasive(s) from settling; 2) minimal, or tunable viscosity reduction even in the presence of shear; 3) maintenance of viscosity even upon extended exposure to shear; and 4) resistance to hard packing of the abrasive.

The rheological properties (including viscosity) of the polishing compositions and vehicles described herein are key properties. For example, the rheological target for these polishing compositions and vehicles requires an operating viscosity range where materials can be stored, pumped and utilized. Too high of a viscosity, and the polishing composition (in the form of a slurry or suspension) cannot adequately be applied to a polishing process. Conversely, too low of a viscosity will allow particles in a polishing composition to settle. As a result, the viscosity in the presently described subject matter is modified using a variety of rheological (viscosity modifying) additives.

For example, in an embodiment, the use of a combination of a first viscosity modifying agent such as hydroxyethyl cellulose (HEC), a second viscosity modifying agent such as polyacrylic acid (PAA), and a pH adjusting agent (also referred to as a partial crosslinking additive) such as diisopropanolamine has been found to provide a stable suspension, wherein at precise concentrations of each component the mixture prevents hard settling and provides controlled viscosity and desired suspension qualities.

The polishing compositions described herein have uses such as, but not limited to, the chemical mechanical polishing of silicon carbide wafers or other materials that traditionally require a large, hard abrasive.

While aspects of the present invention can be described and claimed in a particular statutory class, such as the system statutory class, this is for convenience only and one of skill in the art will understand that each aspect of the present invention can be described and claimed in any statutory class. Unless otherwise expressly stated, it is in no way intended that any method or aspect set forth herein be construed as requiring that its steps be performed in a specific order. Accordingly, where a method claim does not specifically state in the claims or descriptions that the steps are to be limited to a specific order, it is in no way intended that an order be inferred, in any respect. This holds for any possible non-express basis for interpretation, including matters of logic with respect to arrangement of steps or operational flow, plain meaning derived from grammatical organization or punctuation, or the number or type of aspects described in the specification.

### A. DEFINITIONS

Listed below are definitions of various terms used to describe this invention. These definitions apply to the terms as they are used throughout this specification, unless otherwise limited in specific instances, either individually or as part of a larger group.

As used in the specification and the appended claims, the singular forms “a,” “an” and “the” include plural referents unless the context clearly dictates otherwise. Thus, for example, reference to “an abrasive” or “a pH adjusting agent” includes mixtures of two or more such abrasives or pH adjusting agents.

Ranges can be expressed herein as from “about” one particular value, and/or to “about” another particular value. When such a range is expressed, another aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint. It is also understood that there are a number of values disclosed herein, and that each value is also herein disclosed as “about” that particular value in addition to the value itself. For example, if the value “10” is disclosed, then “about 10” is also disclosed. It is also understood that each unit between two particular units is also disclosed. For example, if 10 and 15 are disclosed, then 11, 12, 13, and 14 are also disclosed.

References in the specification and concluding claims to parts by weight of a particular element or component in a composition denote the weight relationship between the element or component and any other elements or components in the composition or article for which a part by weight is expressed. Thus, in a compound containing 2 parts by weight of component X and 5 parts by weight component Y, X and Y are present at a weight ratio of 2:5, and are present in such ratio regardless of whether additional components are contained in the compositions.

A weight percent (wt %) of a component, unless specifically stated to the contrary, is based on the total weight of the vehicle or composition in which the component is included.

As used herein, the term “settle” or “settling” refers to a heterogeneous mixture in which solid particles are initially suspended in the mixture, but over a period of time the solid particles settle to the bottom of the mixture, and/or agglomerate in one portion of the mixture. Upon settling, the solid particles are no longer dispersed or suspended throughout the entire mixture.

As used herein, the terms “optional” and “optionally” mean that the subsequently described event or circumstance can or cannot occur, and that the description includes instances where said event or circumstance occurs and instances where it does not.

### B. POLISHING COMPOSITION AND POLISHING VEHICLE

In one aspect, the subject matter disclosed herein relates to polishing compositions comprising a combination of a first viscosity modifying agent, a second viscosity modifying agent, a pH adjusting agent, an abrasive, and water to provide a stable suspension.

In another aspect, the subject matter disclosed herein relates to a polishing vehicle comprising a first viscosity modifying agent, a second viscosity modifying agent, a pH adjusting agent, and water.

The polishing vehicle and polishing composition are formulated such that they exhibit beneficial properties such as: 1) prevention of the abrasive(s) from settling; 2) minimal viscosity reduction in the presence of shear; 3) maintenance of viscosity upon extended exposure to shear; and 4) resistance to hard packing of the abrasive. As such, the polishing vehicles and polishing compositions described herein successfully maintain the suspension of an abrasive during use in polishing.

1. Viscosity Modifying Agents

In one aspect, the polishing vehicle or polishing composition may comprise one or more viscosity modifying agents. In an embodiment, the polishing vehicle or polishing composition comprises a first viscosity modifying agent and a second viscosity modifying agent, where the two agents are different chemicals.

Viscosity modifying agents are known in the art and are generally associated with causing the viscosity of a medium to increase, i.e., become thicker. As described herein, the viscosity modifying agents may be a cellulose derivative, a polysaccharide, or an anionic polymer. The cellulose derivatives may also be referred to as wetting agents.

Cellulose derivatives for use in the presently disclosed polishing vehicle and polishing compositions include, but are not limited to, hydroxypropylmethylcellulose (HPMC), carboxymethylcellulose (CMC), ethylcellulose, methylcellulose, hydroxyethyl cellulose, ethylhydroxyethyl cellulose, hydroxypropyl cellulose (HPC), microcrystalline cellulose, starch, their salts, and combinations thereof. In an embodiment, the cellulose derivative is hydroxyethyl cellulose. In a further embodiment, the polishing vehicle or polishing composition comprises a first viscosity modifying agent that is hydroxyethyl cellulose.

The cellulose derivatives for use in conjunction with the present disclosure may vary widely in molecular weight, ranging, for example, from 5 kilodaltons (kDa) or less to 20,000 kDa or more, for example, ranging from about 5 kDa to about 10 kDa, from about 10 kDa to about 25 kDa, from about 25 kDa to about 50 kDa, from 50 kDa to about 75 kDa, from about 75 kDa to about 100 kDa, from about 100 kDa to about 250 kDa, from about 250 kDa to about 500 kDa, from about 500 kDa to about 750 kDa, from about 750 kDa to about 1,000 kDa, from about 1,000 kDa to about 2,500 kDa, from about 2,500 kDa to about 5,000 kDa, from about 5,000 kDa to about 7,500 kDa, from about 7,500 kDa to about 10,000 kDa, from about 10,000 kDa to about 15,000 kDa, or from about 15,000 kDa to 20,000 kDa. In some embodiments, the cellulose derivative has a molecular weight of at least about 5 kDa, at least about 10 kDa, at least about 25 kDa, at least about 50 kDa, at least about 75 kDa, at least about 100 kDa, at least about 250 kDa, at least about 500 kDa, at least about 1,000 kDa, at least about 2,500 kDa, at least about 5,000 kDa, at least about 7,500 kDa, at least about 10,000 kDa, at least about 15,000 kDa, or at least about 20,000 kDa. In some embodiments, the cellulose derivative has a molecular weight of less than about 20,000 kDa, less than about 15,000 kDa, less than about 10,000 kDa, less than about 5,000 kDa, less than about 2,500 kDa, less than about 1,000 kDa, less than about 750 kDa, less than about 500 kDa, less than about 250 kDa, less than about 100 kDa, less than about 75 kDa, less than about 50 kDa, less than about 25 kDa, less than about 10 kDa, or less than about 5 kDa.

Polysaccharides for use in the presently disclosed polishing vehicle and polishing compositions include, but are not limited to, xanthan gum, guar gum, locust bean gum, tragacanth gum, gum arabic, acacia gum, agar, sodium alginate, potassium alginate, and combinations thereof. In an embodiment, the polysaccharide is xanthan gum. In a further embodiment, the polishing vehicle or polishing composition comprises a first viscosity modifying agent that is xanthan gum.

The cellulose derivatives and polysaccharides for use in the presently disclosed subject matter are present in specific concentration ranges. For example, the amount of cellulose derivative or polysaccharide is in a range from about 0.05 wt % to about 20 wt %, from about 0.1 wt % to about 10 wt %, from about 0.5 wt % to about 5 wt %, from about 1 wt % to about 4 wt %, or from about 2 wt % to about 3 wt %. In some embodiments, the amount of cellulose derivative or polysaccharide is at least about 0.05 wt %, at least about 0.1 wt %, at least about 0.5 wt %, at least about 1 wt %, at least about 2 wt %, at least about 2.5 wt %, at least about 3 wt %, at least about 4 wt %, or at least about 5 wt %. In some embodiments, the amount of cellulose derivative or polysaccharide is less than about 20 wt %, less than about 15 wt %, less than about 10 wt %, less than about 5 wt %, less than about 4 wt %, less than about 3 wt %, or less than about 2 wt %. In some embodiments, the amount of cellulose derivative or polysaccharide is present at about 0.1 wt %, about 0.2 wt %, about 0.5 wt %, about 1 wt %, about 1.25 wt %, about 2 wt %, about 2.5 wt %, about 3 wt %, about 3.5 wt %, about 4 wt %, or about 5 wt %.

The viscosity modifying agent may also be an anionic polymer. In an embodiment, the anionic polymer is a polyacrylic acid or a polysulfonic acid, or a salt thereof. Non-limiting examples of salts of anionic polymers include ammonium salts, potassium salts, sodium salts and the like.

Polyacrylic acid is a high molecular weight polymer of acrylic acid and is also known as poly(1-carboxyethylene). The polyacrylic acid may be a homopolymer of acrylic acid or crosslinked with other monomers to form polyacrylic acid copolymers. Non-limiting examples of copolymers of polyacrylic acid include polymethacrylic acid, copolymers of methacrylic acid, polyacrylamides, acrylamide copolymers, polymethacrylamides, methacrylamide copolymers, copolymers of C10-30 alkyl acrylates with one or more monomers from the group consisting of acrylic acid, methacrylic acid and their simple esters, and salts thereof.

The polyacrylic acid for use in conjunction with the present disclosure may have a number average molecular weight from 1 kilodalton (kDa) or less to 10,000 kDa or more, for example, ranging from about 1 kDa to about 25 kDa, from about 25 kDa to about 100 kDa, from about 100 kDa to about 500 kDa, from 500 kDa to about 1,000 kDa, or from about 1,000 kDa to about 10,000 kDa. In another embodiment, the polyacrylic acid has a number average molecular weight from about 20 kDa to about 400 kDa. In some embodiments, the polyacrylic acid has a number average molecular weight of at least about 1 kDa, at least about 5 kDa, at least about 10 kDa, at least about 25 kDa, at least about 50 kDa, at least about 75 kDa, at least about 100 kDa, at least about 250 kDa, at least about 500 kDa, at least about 1,000 kDa, at least about 2,500 kDa, at least about 5,000 kDa, or at least about 7,500 kDa. In some embodiments, the polyacrylic acid has a number average molecular weight of less than about 10,000 kDa, less than about 5,000 kDa, less than about 2,500 kDa, less than about 1,000 kDa, less than about 750 kDa, less than about 500 kDa, less than about 250 kDa, less than about 100 kDa, less than about 75 kDa, less than about 50 kDa, less than about 25 kDa, less than about 10 kDa, less than about 5 kDa, or less than about 1 kDa. In additional embodiments, low number average molecular weight polyacrylic acids may be used, such as polyacrylic acids having a number average molecular weight from about 1 kDa to about 10 kDa or about 2 kDa to about 8 kDa. If a blend or mixture of two polyacrylic acids is used, the blend may comprise a low number average molecular weight polyacrylic acid and a high number average molecular weight polyacrylic acid. In an embodiment, in the blend, the low number average molecular weight polymer may have a number average molecular weight of about 1 kDa to about 100 kDa and the high number average molecular weight polyacrylic acid has a molecular weight of about 200 kDa to about 10,000 kDa. In additional embodiments, the polyacrylic acid has a number average molecular weight of about 1 kDa, about 2 kDa, about 10 kDa, about 25 kDa, about 50 kDa, about 100 kDa, about 500, kDa, about 1,000 kDa, about 1,250 kDa, about 2,500 kDa, about 4,000 kDa, about 5,000 kDa, or about 10,000 kDa. Polyacrylic acids are commercially available from many vendors, such as those sold under the trade name Carbopol.

The polyacrylic acids are formed by polymerizing monomers or mixtures of monomers. When one monomer is used, the polyacrylic acid is a homopolymer. Thus, the polyacrylic acid may be a homopolymer of acrylic acid. In an alternative embodiment, the polyacrylic acid may include other monomers. In such an embodiment, the polyacrylic acid may contain acrylic acid monomers and be crosslinked with other monomers, such as an allyl ether of pentaerythritol, allyl ether of sucrose, or allyl ether of propylene. In an embodiment, the polyacrylic acid may be formed from a monomer with a molecular weight of about 70 g/mol.

Also, it is possible to form polyacrylic acid copolymers that are biodegradable, photodegradable, or degradable by other means. An example of such a copolymer is a biodegradable polyacrylic acid containing segments of poly(acrylate-co-methyl 2-cyanoacrylate).

The anionic polymer can also be sulfonate (SO₃⁻) based or phosphate based (PO₄³⁻) and contains hydrocarbon groups as a backbone moiety. In one embodiment, the sulfonate or phosphate based anionic polymer is an anionic surfactant. Some non-limiting examples of sulfonate/sulfate based anionic surfactants are lauryl ether sulfate, and sulfate based Triton surfactants from Dow Chemical such as TRITON Q-15, XN-455, and W-30 series. Some non-limiting examples of phosphate based anionic surfactants/polymers are the Triton series from Dow Chemical such as TRITON H-55, and H-66.

The anionic polymer for use in the presently disclosed subject matter may be present in specific concentration ranges. For example, the amount of anionic polymer is in a range from about 0.01 wt % to about 2 wt %, from about 0.05 wt % to about 1 wt %, from about 0.1 wt % to about 0.5 wt %, or from about 0.08 wt % to about 0.2 wt %. In some embodiments, the amount of anionic polymer is at least about 0.01 wt %, at least about 0.05 wt %, at least about 0.1 wt %, at least about 0.2 wt %, at least about 0.3 wt %, at least about 0.4 wt %, or at least about 0.5 wt %. In some embodiments, the amount of anionic polymer is less than about 2 wt %, less than about 1 wt %, less than about 0.5 wt %, less than about 0.25 wt %, or less than about 0.1 wt %. In some embodiments, the amount of anionic polymer is present at about 0.05 wt %, about 0.08 wt %, about 0.1 wt %, about 0.2 wt %, about 0.4 wt %, or about 0.6 wt %.

In an embodiment, the polishing vehicle or polishing composition comprises both a first and second viscosity modifying agent. The first and second viscosity modifying agents may be present in varying amounts as specified herein. Regardless of the actual amounts, the first and second viscosity modifying agents may be present in a wt % ratio of the first agent to second agent. For example, the ratio of the first viscosity modifying agent to second viscosity modifying agent may be about 1:1, about 5:1, about 10:1, about 25:1, about 30:1, about 40:1, about 50:1, about 75:1, or about 100:1. In some embodiments, the ratio of the first viscosity modifying agent to second viscosity modifying agent may be in a range from about 1:1 to about 100:1, from about 5:1 to about 75:1, from about 10:1 to about 50:1, or from about 25:1 to about 40:1.

The polishing vehicles and polishing compositions described herein have viscosities adjusted by the various viscosity adjusting agents described herein. The viscosity of the polishing vehicles and polishing compositions described herein is quantified using the CGS unit (g·cm⁻¹·s⁻¹) and commonly referred to as centipoise (cP), where 1 cP=0.01g·cm⁻¹·s⁻¹.

In embodiments, the polishing vehicles and polishing compositions described herein have a viscosity in the range from about 10 cP to about 300 cP, from about 20 cP to about 250 cP, from about 30 cP to about 200 cP, from about 40 cP to about 150 cP, from about 50 cP to about 100 cP, or from about 60 cP to about 90 cP. In embodiments, the polishing vehicles and polishing compositions have a viscosity of at least about 40 cP, at least about 50 cP, at least about 60 cP, at least about 70 cP, at least about 80 cP, at least about 90 cP, at least about 100 cP, at least about 150 cP, at least about 200 cP, or at least about 250 cP. In embodiments, the polishing vehicles and polishing compositions have a viscosity of about 20 cP, about 40 cP, about 70 cP, about 75 cP, about 80 cP, about 85 cP, about 90 cP, about 100 cP, about 125 cP, about 150 cP, about 200 cP, about 250 cP, or about 300 cP.

The polishing vehicles and polishing compositions described herein may have the same viscosity, similar viscosity, or a very different viscosity depending on whether the viscosity is measured pre-shear or post-shear. In embodiments, the viscosity measured pre-shear and post-shear is similar or the same, indicating that the polishing vehicle or polishing composition is resistant to shear. For example, the viscosity measured pre-shear and post-shear may have no difference, about a 1% difference, about a 2% difference, about a 5% difference, about a 10% difference, about a 15% difference, about a 20% difference, about a 25% difference, about a 30% difference, about a 35% difference, or about a 40% difference. In some embodiments, the difference may be at least about 1%, at least about 5%, at least about 10%, at least about 15%, at least about 20%, at least about 25%, at least about 30%, or at least about 35%

The polishing vehicles and polishing compositions described herein may show shear stability or resistance to shear even if there is a large difference in viscosity measured pre-shear and post-shear. For example, if the viscosity difference between pre-shear and post-shear measurements is large but the polishing composition has a viscosity high enough to successfully suspend the abrasive, the polishing vehicle and polishing composition may be sufficiently shear resistant.

2. pH Adjusting Agent

The polishing vehicles and polishing compositions of this disclosure optionally contain at least one pH adjusting agent to control the pH. In an embodiment, the pH adjusting agent is a basic compound. The basic compound may be appropriately selected from various basic compounds that have a function of raising the pH of aqueous solutions in which the compounds are dissolved. For example, an organic or inorganic basic compound containing nitrogen, an alkali metal hydroxide, an alkaline earth metal hydroxide, various carbonates, bicarbonates and the like may be used. Examples of the nitrogen-containing basic compound include a quaternary ammonium compound, a quaternary phosphonium compound, ammonia, an amine and the like. As the amine, a water-soluble amine is preferable. Such basic compounds may be used singly or in combination of two or more types thereof.

Specific examples of the alkali metal hydroxide include potassium hydroxide, sodium hydroxide and the like. Specific examples of the carbonate and bicarbonate include ammonium hydrogen carbonate, ammonium carbonate, potassium hydrogen carbonate, potassium carbonate, sodium hydrogen carbonate, sodium carbonate and the like. Specific examples of the amine include methylamine, dimethylamine, trimethylamine, ethylamine, diethylamine, triethylamine, ethylenediamine, monoethanolamine, diisopropanolamine, N-(3-aminoethyl) ethanolamine, hexamethylenediamine, diethylenetriamine, triethylenetetramine, piperazine anhydride, piperazine hexahydrate, 1-(2-aminoethyl) piperazine, N-methylpiperazine, guanidine, azoles such as imidazole and triazole and the like. Specific examples of the quaternary phosphonium compound include a quaternary phosphonium hydroxide such as tetramethylphosphonium hydroxide and tetraethylphosphonium hydroxide.

A quaternary ammonium salt such as a tetraalkylammonium salt or a hydroxyalkyltrialkylammonium salt may be preferably used as the quaternary ammonium compound. The anion component of the quaternary ammonium salt may be, for example, OH⁻, F⁻, Cl⁻, Br⁻, I⁻, ClO₄ and BH₄⁻. The quaternary ammonium salt is preferably a strong base. Among others, a quaternary ammonium salt with OH— as an anion, that is, a quaternary ammonium hydroxide, may be mentioned as a preferable example. Specific examples of the quaternary ammonium hydroxide include a tetraalkylammonium hydroxide such as tetramethylammonium hydroxide, tetraethylammonium hydroxide, tetrapropylammonium hydroxide, tetrabutylammonium hydroxide, tetrapentylammonium hydroxide and tetrahexylammonium hydroxide, a hydroxyalkyltrialkylammonium hydroxide such as 2-hydroxyethyltrimethylammonium hydroxide (also referred to as choline), and the like.

In an embodiment, the pH of the polishing vehicle or polishing composition is adjusted to a range that is from about 2 to about 10, from about 3 to about 9, from about 4 to about 8, or from about 5 to about 7. In some embodiments, the pH is less than about 10, less than about 9, less than about 8, less than about 7, less than about 6, less than about 5, less than about 4, or less than about 3. In some embodiments, the pH is about 2, 3, 4, 5, 6, 7, 8, 9, or 10. In some embodiments, the pH is more than about 1, more than about 2, more than about 3, more than about 4, more than about 5, more than about 6, more than about 7, more than about 8, or more than about 9.

The pH adjusting agent may be present at a specific concentration range, regardless of pH. For example, the amount of pH adjusting agent is in a range from about 0.001 wt % to about 0.1 wt %, from about 0.005 wt % to about 0.05 wt %, or from about 0.01 wt % to about 0.025 wt %. In some embodiments, the pH adjusting agent is present in an amount of at least about 0.001 wt %, at least about 0.005 wt %, at least about 0.01 wt %, at least about 0.025 wt %, at least about 0.05 wt %, at least about 0.075 wt %, or at least about 0.1 wt %. In some embodiments, the pH adjusting agent is present in an amount of about 0.0075 wt %, about 0.01 wt %, about 0.025 wt %, about 0.05 wt %, about 0.075 wt %, or about 0.014 wt %.

In alternate embodiments, the pH adjusting agent may be acidic in nature or may be a mixture of an acidic agent and basic agent (such as a buffer). The choice of acid is not particularly limited provided that the strength of the acid is sufficient to lower the pH of the polishing composition of the present invention. Non-limiting examples of acids are hydrochloric acid, nitric acid, sulfuric acid, chloroacetic acid, tartaric acid, succinic acid, citric acid, malic acid, malonic acid, and phosphoric acid.

3. Abrasive

The polishing vehicle described herein may further contain an abrasive. The material and properties of the abrasive included in the polishing composition disclosed herein are not particularly limited and can be appropriately selected according to the purpose of use and application of the polishing composition. Examples of abrasives include oxide particles such as silica particles, alumina particles, cerium oxide particles, chromium oxide particles, titanium dioxide particles, zirconium oxide particles, magnesium oxide particles, manganese dioxide particles, zinc oxide particles, red iron oxide particles and the like; nitride particles such as silicon nitride particles, boron nitride particles and the like; carbide particles such as silicon carbide particles, boron carbide particles and the like; diamond particles; and carbonates such as calcium carbonate, barium carbonate and the like. Such abrasives may be used singly or in combination of two or more types thereof.

The type and size of these abrasives may be selected in consideration of the mechanical function of the abrasives. For example, in order to increase the removal rate of material from the substrate, abrasives of high hardness and large size may be used. In another example, in order to decrease surface roughness of the polished substrate, abrasives of low hardness and small size may be used. In still another example, in order to shorten the polishing time and obtain a smooth surface, a multistep lapping or polishing procedure may be used where the procedure includes using abrasives of larger size in one step and using abrasives of smaller size in another step.

The abrasive can have any suitable particle size. The abrasive can have an average particle size of about 50 nm or more, about 100 nm or more, about 500 nm or more, about 1,000 nm or more, about 5,000 nm or more, about 10,000 nm or more, about 25,000 nm or more, or about 50,000 nm or more. Alternatively, or in addition, the abrasive can have an average particle size of about 50,000 nm or less, about 25,000 nm or less, about 10,000 nm or less, about 5,000 nm or less, about 2,500 nm or less, about 1,000 nm or less, about 500 nm or less, about 200 nm or less, about 150 nm or less, about 100 nm or less, or about 50 nm or less. For example, in embodiments, the abrasive can have an average particle size in a range from about 50 nm to about 100 nm, from about 100 nm to about 500 nm, from about 500 nm to about 1,000 nm, from about 1,000 nm to about 5,000 nm, from about 5,000 nm to about 10,000 nm, from about 10,000 nm to about 25,000 nm, or from about 25,000 nm to about 50,000 nm. The particle size of a particle is the diameter of the smallest sphere that encompasses the particle. The average particle size of the abrasive can be measured by a particle size analyzer (Horiba Particle Size Distribution tool).

The amount of abrasive in the polishing composition can be about 0.01 wt % or more, about 0.05 wt % or more, about 0.1 wt % or more, about 0.2 wt % or more, about 0.3 wt % or more, about 0.5 wt % or more, about 1 wt % or more, about 5 wt % or more, about 7 wt % or more, or about 10 wt % or more. Alternatively, or in addition, the amount of abrasive in the polishing composition can be about 30 wt % or less, about 25 wt % or less, about 20 wt % or less, about 15 wt % or less, about 10 wt % or less, about 5 wt % or less, about 3 wt % or less, about 1 wt % or less, about 0.8 wt % or less, about 0.7 wt % or less, about 0.6 wt % or less, or about 0.5 wt % or less. In embodiments, the amount of abrasive in the polishing composition can be in a range from about 0.01 wt % to about 30 wt %, about 0.05 wt % to about 10 wt %, from about 0.1 wt % to about 5 wt %, from about 0.25 wt % to about 4 wt %, from about 0.5 wt % to about 3 wt %, or from about 0.75 wt % to about 2 wt %. In some embodiments, the amount of abrasive is about 0.1 wt %, about 0.25 wt %, about 0.5 wt %, about 0.75 wt %, about 1 wt %, about 2 wt %, about 3 wt %, about 4 wt %, or about 5 wt %.

While the abrasive can be of any reasonable size, the size of the abrasive influences the smoothness of the finish obtained. Precision polishing operations materials such as optical components, plastics, metals, gemstones, semiconductor components, and the like typically involve the use of abrasives with smaller sizes and present particular problems. For example, compositions for use in connection with precision polishing involve suspensions of abrasives with smaller average particle sizes. However, it is extremely difficult to maintain the abrasive particles in suspension in the carrier medium, particularly considering the relatively small amount of abrasives present compared to the large amount of medium in such compositions.

In an embodiment the abrasive is substantially composed of diamond particles. As used herein, “substantially” means that 95% by weight or more, preferably 98% by weight or more, more preferably 99% by weight or more of the particles constituting the abrasive are diamond particles, and it includes that 100% by weight of the particles are diamond particles.

4. Water

In an embodiment, the polishing vehicles or polishing compositions disclosed herein contain a carrier medium, or vehicle, wherein that medium or vehicle is water. Ion exchanged water (deionized water), pure water, ultrapure water, distilled water and the like may be used as the water. In order to reduce the amount of unwanted components present in the water, the purity of water may be increased by operations such as removal of impurity ions with an ion exchange resin, removal of contaminants with a filter, and/or distillation.

In some embodiments, the water is relatively free of impurities. In some embodiments, the water contains less than about 10% w/w, about 9% w/w, about 8% w/w, about 7% w/w, about 6% w/w, about 5% w/w, about 4% w/w, about 3% w/w, about 2% w/w, about 1% w/w, about 0.9% w/w, about 0.8% w/w, about 0.7% w/w, about 0.6% w/w, about 0.5% w/w, about 0.4% w/w, about 0.3% w/w, or less than about 0.1% w/w of impurities based on the total weight of the water.

5. Additional Components

In an embodiment, the polishing vehicles and polishing compositions disclosed herein may contain additional components such as biocides, surfactants, oxidizers, corrosion inhibitors, or co-solvents. Additionally or alternatively, the vehicles and compositions disclosed herein can include other additives as will be understood by those skilled in the art.

In an embodiment, the additional component may be a biocide. Non-limiting examples of biocides include hydrogen peroxide, quaternary ammonium compounds, and chlorine compounds. More specific examples of the quaternary ammonium compounds include, but are not limited to, methylisothiazolinone, tetramethylammonium chloride, tetraethylammonium chloride, tetrapropylammonium chloride, alkylbenzyldimethylammonium chloride, and alkylbenzyldimethylammonium hydroxide, wherein the alkyl chain ranges from 1 to about 20 carbon atoms. More specific examples of the chlorine compounds include, but are not limited to, sodium chlorite and sodium hypochlorite. Additional examples of biocides include biguanide, aldehydes, ethylene oxide, isothiazolinone, iodophor, KATHON™ and NEOLENE™ product families that are commercially available from Dow chemicals, and the Preventol™ family from Lanxess. The amount of biocide used in the polishing composition may range from about 0.0001 wt % to 0.10 wt %, preferably from 0.0001 wt % to 0.005 wt %, and more preferably from 0.0002 wt % to 0.0025 wt %.

In another embodiment, the additional component may include a surfactant. The surfactants may be anionic, cationic, nonionic, or zwitterionic and may increase lubricity of the vehicle or compositions. Non-limiting examples of the surfactants are dodecyl sulfates, sodium salts or potassium salts, lauryl sulfates, secondary alkane sulfonates, alcohol ethoxylate, acetylenic diol surfactant, quaternary ammonium-based surfactants, amphoteric surfactants, such as betaines and amino acid derivatives-based surfactants, and any combination thereof. Examples of suitable commercially available surfactants include TRITON™, Tergitol™, DOWFAX™ family of surfactants manufactured by Dow Chemicals and various surfactants in SURFYNOL™, DYNOL™, Zetasperse™, Nonidet™, and Tomadol™ surfactant families, manufactured by Air Products and Chemicals. Suitable surfactants of surfactants may also include polymers comprising ethylene oxide (EO) and propylene oxide (PO) groups. An example of EO-PO polymer is Tetronic™ 90R4 from BASF Chemicals. An example of acetylenic diol surfactant is Dynol™ 607 from Air Products and Chemicals. The amount of surfactant used in the polishing composition may range from about 0.0005 wt % to 0.15 wt %, preferably from 0.001 wt % to 0.05 wt %, and more preferably from 0.0025 wt % to 0.025 wt %.

In another embodiment, the additional component may include an oxidizer. Non-limiting examples of the oxidizer include periodic acid, hydrogen peroxide, potassium iodate, potassium permanganate, ammonium persulfate, ammonium molybdate, ferric nitrate, nitric acid, potassium nitrate, and mixtures thereof. The amount of oxidizer may range from about 0.1 wt % to 10 wt %, preferably from 0.25 wt % to 3 wt %, and more preferably from 0.5 wt % to 1.5 wt % oxidizer.

In another embodiment, the additional component may include a corrosion inhibitor. Non-limiting examples of the corrosion inhibitor may include 1,2,4-triazole and its derivatives, benzotriazole and its derivatives, 1,2,3-triazole and its derivatives, pyrazole and its derivatives, imidazole and its derivatives, benzimidazole and its derivatives, isocyanurate and its derivatives, and mixtures thereof. The amount of corrosion inhibitor in the polishing composition may range from about 0.0005 wt % to 0.25 wt %, preferably from 0.0025 wt % to 0.15 wt %, and more preferably from 0.05 wt % to 0.1 wt % of corrosion inhibitor.

In another embodiment, the additional component may include another solvent, termed a co-solvent. Non-limiting examples of co-solvents include, but are not limited to, alcohols, preferably lower alkanols such as methanol or ethanol, ethyl acetate, tetrahydrofuran, alkanes, tetrahydrofuran, dimethylformamide, toluene, ketones such as acetone, aldehydes, and esters, dimethyl formamide, dimethyl sulfoxide, pyridine, acetonitrile, glycols, and mixtures thereof. The amount of the co-solvent may be employed in various amounts, preferably from a lower limit of about 0.1, 0.5, 1, 5, or 10% (w/v) to an upper limit of about 5, 10, 15, 20, 25, or 35% (w/v).

In some embodiments, the polishing vehicle comprises only a first viscosity modifying agent, a second modifying agent, a pH adjusting agent, and water. In some embodiments, the polishing composition comprises only a first viscosity modifying agent, a second modifying agent, a pH adjusting agent, an abrasive, and water. In an alternate embodiment, the polishing vehicle or polishing composition does not comprise an additional carrier medium, such as a polyol, exemplified by ethylene glycol or glycerol (glycerin).

As disclosed herein, in an embodiment, is a polishing composition comprising a first viscosity modifying agent, a second viscosity modifying agent, a pH adjusting agent, an abrasive, and water, wherein the first viscosity modifying agent comprises a cellulose derivative or a polysaccharide; the second viscosity modifying agent comprises an anionic polymer; the pH adjusting agent comprises an inorganic or amine base; and the abrasive has an average particle size of about 50 nm or more.

As in any above embodiment, a polishing composition wherein the first viscosity modifying agent is a cellulose derivative selected from the group consisting of hydroxypropylmethylcellulose (HPMC), carboxymethylcellulose (CMC), ethylcellulose, methylcellulose, hydroxyethyl cellulose, ethylhydroxyethyl cellulose, hydroxypropyl cellulose (HPC), microcrystalline cellulose, starch, their salts, and combinations thereof.

As in any above embodiment, a polishing composition wherein the first viscosity modifying agent is hydroxyethyl cellulose.

As in any above embodiment, a polishing composition wherein the first viscosity modifying agent is a polysaccharide selected from the group consisting of xanthan gum, guar gum, locust bean gum, tragacanth gum, gum arabic, acacia gum, agar, sodium alginate, potassium alginate, their salts, and combinations thereof.

As in any above embodiment, a polishing composition wherein the first viscosity modifying agent is xanthan gum.

As in any above embodiment, a polishing composition wherein the first viscosity modifying agent is present in an amount from about 0.5 wt % to about 5 wt %.

As in any above embodiment, a polishing composition wherein the anionic polymer is selected from the group consisting of a polyacrylic acid, a polysulfonic acid, and salts thereof.

As in any above embodiment, a polishing composition wherein the anionic polymer is a polyacrylic acid or a salt thereof.

As in any above embodiment, a polishing composition wherein the weight average molecular weight of the polyacrylic acid is from about 20 kDa to about 400 kDa.

As in any above embodiment, a polishing composition wherein the anionic polymer is present in an amount from about 0.05 wt % to about 1 wt %.

As in any above embodiment, a polishing composition wherein the base is an amine base selected from the group consisting of trimethylamine and diisopropanolamine.

As in any above embodiment, a polishing composition wherein the base is an inorganic base selected from the group consisting of KOH and NaOH.

As in any above embodiment, a polishing composition wherein the pH of the polishing composition is from about 3 to about 9.

As in any above embodiment, a polishing composition wherein the pH adjusting agent is present in an amount from about 0.001 wt % to about 0.1 wt % of the total weight of the polishing composition.

As in any above embodiment, a polishing composition wherein the abrasive is selected from the group consisting of silica particles, alumina particles, cerium oxide particles, chromium oxide particles, titanium dioxide particles, zirconium oxide particles, magnesium oxide particles, manganese dioxide particles, zinc oxide particles, red iron oxide particles, silicon nitride particles, boron nitride particles, silicon carbide particles, boron carbide particles, diamond particles, calcium carbonate, barium carbonate, and combinations thereof.

As in any above embodiment, a polishing composition wherein the abrasive is substantially composed of diamond particles.

As in any above embodiment, a polishing composition wherein the viscosity of the polishing composition is from about 50 cP to about 100 cP.

As in any above embodiment, a polishing composition wherein the polishing composition has about a 25% difference in viscosity between the pre-shear and post-shear measurements.

As in any above embodiment, a polishing composition wherein the first viscosity modifying agent comprises hydroxyethyl cellulose or xanthan gum and is present in an amount from about 0.5 wt % to about 5 wt %; the second viscosity modifying agent comprises a polyacrylic acid with a weight number average molecular weight from about 20 kDa to about 400 kDa and is present in an amount from about 0.05 wt % to about 1 wt %; the pH adjusting agent is selected from the group consisting of trimethylamine, diisopropanolamine, KOH, and NaOH, and is present in an amount from about 0.001 wt % to about 0.1 wt %; the abrasive is diamond; and the polishing composition has about a 5% difference in viscosity between the pre-shear and post-shear measurements.

As in any above embodiment, a polishing composition wherein the first viscosity adjusting agent is hydroxyethyl cellulose which is present in an amount from about 2 wt % to about 3 wt %, the polyacrylic acid is present in an amount from about 0.08 wt % to about 0.2 wt %, the pH adjusting agent is diisopropanolamine, which is present in an amount from about 0.01 wt % to about 0.025 wt %, and the polishing composition has a viscosity from about 50 cP to about 100 cP.

As in any above embodiment, a polishing vehicle or polishing composition, wherein the viscosity of the composition is 50 to 500 cP in the working vehicle formulation, and 50-10,000 cP in the concentrated vehicle formulation. The difference between the working vehicle and the concentrate vehicle is that the concentrate may have about 5 times (i.e., 5×) less volume of solvent present. In an embodiment, the concentrated vehicle formulation may have about 2×, 3×, 4×, 5×, 6×, 7×, 8×, 9×, or 10× less solvent volume when compared to the working vehicle formulation.

As disclosed herein, in an embodiment, is a polishing vehicle comprising a first viscosity modifying agent, a second viscosity modifying agent, a pH adjusting agent, and water, wherein the first viscosity modifying agent comprises hydroxyethyl cellulose or xanthan gum present in an amount from about 0.5 wt % to about 5 wt %; the second viscosity modifying agent comprises a polyacrylic acid present in an amount from about 0.05 wt % to about 1 wt %; the pH adjusting agent is selected from the group consisting of trimethylamine, diisopropanolamine, KOH, and NaOH, wherein the pH adjusting agent is present in an amount from about 0.001 to about 0.1 wt %; and wherein the wt % is a wt % of the entire vehicle.

As in any above embodiment, a polishing vehicle wherein the first viscosity modifying agent is hydroxyethyl cellulose.

As in any above embodiment, a polishing vehicle wherein the first viscosity modifying agent is xanthan gum.

As in any above embodiment, a polishing vehicle wherein the polyacrylic acid has a weight number average molecular weight from about 20 kDa to about 400 kDa.

As in any above embodiment, a polishing vehicle wherein the pH adjusting agent is diisopropanolamine.

As in any above embodiment, a polishing vehicle wherein the pH of the polishing vehicle is from about 3 to about 9.

As in any above embodiment, a polishing vehicle wherein the viscosity of the polishing composition is about 50 cP to about 100 cP.

As in any above embodiment, a polishing vehicle wherein the polishing vehicle has about a 5% difference in viscosity between the pre-shear and post-shear measurements.

As in any above embodiment, a polishing vehicle wherein the first viscosity modifying agent is hydroxyethyl cellulose, the second viscosity modifying agent is a polyacrylic acid with a weight number average molecular weight from about 20 kDa to about 400 kDa, and the pH adjusting agent is diisopropanolamine.

As in any above embodiment, a polishing vehicle wherein hydroxyethyl cellulose is present in an amount from about 2 wt % to about 3 wt %, the polyacrylic acid is present in an amount from about 0.08 wt % to about 0.2 wt %, and diisopropanolamine is present in an amount from about 0.01 wt % to about 0.025 wt %.

### C. METHODS OF USING THE POLISHING COMPOSITIONS

The polishing compositions described herein are useful for polishing any suitable substrate. In an embodiment, the substrate to be polished can be any suitable substrate which comprises at least one layer of silicon carbide. Suitable substrates include, but are not limited to, flat panel displays, integrated circuits, memory or rigid disks, metals, interlayer dielectric (ILD) devices, semiconductors, micro-electro-mechanical systems, ferroelectrics, and magnetic heads. The silicon carbide can comprise, consist essentially of, or consist of any suitable silicon carbide, many of which are known in the art. The silicon carbide can be single crystal. Silicon carbide has many different types of crystal structures, each having its own distinct set of electronic properties. Only a small number of these polytypes, however, can be reproduced in a form acceptable for use as semiconductors. Such polytypes can be either cubic (e.g., 3C silicon carbide) or non-cubic (e.g., 4H silicon carbide, 6H silicon carbide). The properties of these polytypes are well known in the art.

As another example, the polishing composition can be used to polish a substrate comprising a silicon oxide layer. In another embodiment, the polishing composition can be used to polish a substrate comprising a silicon layer. Suitable substrates include, but are not limited to, flat panel displays, integrated circuits, memory or rigid disks, metals, semiconductors, interlayer dielectric (ILD) devices, microelectromechanical systems (MEMS), ferroelectrics, and magnetic heads.

The substrate can further comprise at least one other layer, e.g., an insulating layer. The insulating layer can be a metal oxide, porous metal oxide, glass, organic polymer, fluorinated organic polymer, or any other suitable high or low-K insulating layer. The insulating layer can comprise, consist essentially of, or consist of silicon oxide, silicon nitride, or combinations thereof. The silicon oxide layer can comprise, consist essentially of, or consist of any suitable silicon oxide, many of which are known in the art. For example, the silicon oxide layer can comprise tetraethoxysilane (TEOS), high density plasma (HDP) oxide, borophosphosilicate glass (BPSG), high aspect ratio process (HARP) oxide, spin on dielectric (SOD) oxide, chemical vapor deposition (CVD) oxide, plasma-enhanced tetraethyl ortho silicate (PETEOS), thermal oxide, or undoped silicate glass. The substrate can further comprise a metal layer. The metal can comprise, consist essentially of, or consist of any suitable metal, many of which are known in the art, such as, for example, copper, tantalum, tungsten, titanium, platinum, ruthenium, iridium, aluminum, nickel, or combinations thereof.

The subject matter disclosed herein also comprises a method for polishing a substrate with the polishing compositions described herein. The method of polishing a substrate comprises: (a) providing a substrate, (b) providing a polishing composition described herein, (c) applying the polishing composition to at least a portion of the substrate, and (d) abrading at least a portion of the substrate with the polishing composition to polish the substrate.

### D. EXAMPLES

The following preparations and examples are given to enable those skilled in the art to more clearly understand and to practice the present invention. They should not be considered as limiting the scope of the invention, but merely as being illustrative and representative.

In one aspect, disclosed are methods of making the polishing compositions. In another aspect are disclosed methods of using the polishing compositions to polish materials.

### Example 1: Procedure for Preparing the Polishing Compositions

The polishing compositions of Formulations 1 to 8, each having a pH of about 4.5 were prepared by mixing the following materials in deionized water so as to have the composition described in Table 1 (mixing temperature: about 20° C., mixing time: about 5 minutes). The pH of each of the polishing compositions (liquid temperature: 20° C.) was measured by a pH meter.
Abrasive (polycrystalline diamond particles, average particle size: about 3,000 nm)
First Viscosity Modifying Agent (Hydroxyethyl cellulose (HEC), weight average molecular weight: about 150,000)
Second Viscosity Modifying Agent (Polyacrylic acid (PAA), cross-linked high-molecular-weight acrylic acid copolymer of acrylate and C10-C30 alkyl acrylate)
pH Adjusting Agent (Diisopropanolamine (DIP))
   The characteristics of each polishing composition are summarized in Table 1.

### Example 2: Viscosity and Shear Testing

Shear Resistance

The shear resistance was measured using a diaphragm pump moving each polishing composition through a loop system for 24 hours at a flow rate of 600 ml/min. For the first 1 to 3 hours the polishing composition was tested using a viscometer (Brookfield Programmable DV-II+ viscometer) to measure viscosity. The spindle was LV-1 and the speed was 5-20 RPMs. After the viscosity stabilizes, testing occurs every hour for the duration of the 24-hour period. The shear resistance was labeled as “pass” when the polishing composition had no viscosity loss over the 24-hour testing cycle, or minimal loss but stabilized at a viscosity above water during the testing. If the shear resistance did not meet either of these parameters, it was labeled as “fail.”

Dispersion

The dispersion of the abrasive in the polishing composition was measured by a particle size analyzer (Horiba Particle Size Distribution tool). The dispersion was labeled as “pass” when the average particle size matched closely with the manufacturer size specification. For example, the manufacturer-provided size specification may be 3,000 nm. When the particle size analyzer provided a particle size of about 3,000 nm (i.e., within 3 sigma of the specification), the dispersion was labeled as “pass.”

Settling

The settling was assessed by comparing the polishing composition with a control composition side by side. Formulation 5 was typically used as a control composition in this settling test. The test was carried out over the course of about 2-24 hours after exposure to shear. The polishing composition getting a passing grade settled slower than the control composition. For example, the control composition may completely settle in an hour while the polishing composition of the present invention did not settle after 24 hours.

Hard Packing

The hard packing was measured as follows. The polishing composition was placed in a PP bottle and allowed to settle for 1 week. After settling, the PP bottle was inverted and observed for 20 minutes. If the abrasive flowed evenly (no congealed mass) and the bottom of the bottle was left clean after 20 minutes the bottle was inverted and opened. The hard packing was a pass when there was no congealed mass of abrasive stuck to the lid.

(Evaluation of Polishing)

Polishing was performed under the following testing conditions, and the polishing removal rate was determined. In addition, the surface roughness of each substrate to be polished after polishing was measured by the following method:

Testing Conditions:

Polishing machine—ENGIS EJ-380BX (380 mm=15 inch plates)

Polishing pressure—220 g/cm² (3.1 psi)

Rotation speed—100 r.p.m. (Linear velocity 1.5 m/sec)

Slurry feed rate—10 mL/min (One-way)

Polishing pad—SUBA 500

Wafer—4 inch 4H-n SiC (4 degree offset)—1 piece/plate

Fixing tool—Template, suede backing pad

Polish time—30 minutes

Polishing Removal Rate

The polishing removal rate was calculated according to the following calculation formulae (1) and (2).

Polishing removal [cm]=a difference in weight of SiC wafer before and after polishing [g]/density of SiC [g/cm³](=3.21 g/cm³)/polishing target area [cm²](=19.62 cm²) (1)

Polishing removal rate [nm/min]=polishing removal [cm]×10⁷/polishing time [min](=30 minutes) (2)

Surface Roughness

The surface roughness of the substrate to be polished after polishing was measured using an atomic force microscope (NX-HDM manufactured by Park Systems). The surface roughness is a parameter that indicates the average amplitude of the roughness curve in the height direction, and shows the arithmetical mean height of the surface of the substrate to be polished within a certain field of view.

Various polishing vehicles and polishing compositions were prepared and tested using the above methods. The components of the various polishing vehicles and polishing compositions are presented in Table 1. The results from the polishing and shear testing are presented in Tables 1-4.

TABLE 1

| | | | First | | Second | | | | | | | | | |
|---|---|---|---|---|---|---|---|---|---|---|---|---|---|---|
| | | | Viscosity | | Viscosity | | pH | | Shear | | | | | |
| | | | Modifying | | Modifying | | Adjusting | | Resistance | | | | | |
| | Abrasive | | Agent | | Agent | | Agent | | Initial | Post | | | | |
| | | amount | | amount | | amount | | amount | Viscosity | Viscosity | | | | Hard |
| Form # | type | (wt %) | type | (wt %) | type | (wt %) | type | (wt %) | (cP) | (cP) | | Dispersion | Settling | packing |
| 1 | Diamond | 1 | HEC | 2.5 | PAA | 0.08 | DIP | 0.01 | 84 | 74 | PASS | PASS | PASS | PASS |
| 2 | Diamond | 1 | HEC | 2 | PAA | 0.08 | DIP | 0.01 | 40 | 43 | PASS | PASS | | |
| 3 | Diamond | 1 | HEC | 2.5 | PAA | 0.1 | DIP | 0.0125 | 104 | 79 | | PASS | PASS | PASS |
| 4 | Diamond | 1 | HEC | 3 | PAA | 0.08 | DIP | 0.01 | 180 | 131 | | PASS | PASS | PASS |
| 5 | Diamond | 1 | — | — | — | — | — | — | | | | PASS | FAIL | FAIL |
| 6 | Diamond | 1 | — | — | PAA | 0.08 | — | — | | | | FAIL | N/A | N/A |
| 7 | Diamond | 1 | HEC | 5 | — | — | — | — | 277 | 281 | | PASS | PASS | FAIL |
| 8 | Diamond | 5 | — | — | PAA | 0.4 | DIP | 0.05 | | | FAIL | PASS | PASS | PASS |

TABLE 2

| | | | First | | First | | | | | | | |
|---|---|---|---|---|---|---|---|---|---|---|---|---|
| | | | Viscosity | | Viscosity | | pH | | | | Surface | |
| | | | Modifying | | Modifying | | Adjusting | | RR | | Roughness | |
| | Abrasive | | Agent | | Agent | | Agent | | (um/min) | | (nm) | |
| | | amount | | amount | | amount | | amount | Pre- | Post- | Pre- | Post- |
| Form # | type | (wt %) | type | (wt %) | type | (wt %) | type | (wt %) | shear | shear | shear | shear |
| 1 | Diamond | 1 | HEC | 2.5 | PAA | 0.08 | DIP | 0.01 | 0.23 | 0.18 | 1.66 | 2.4 |
| 3 | Diamond | 1 | HEC | 2.5 | PAA | 0.1 | DIP | 0.0125 | 0.23 | 0.09 | 1.64 | 9.44 |
| 4 | Diamond | 1 | HEC | 3 | PAA | 0.08 | DIP | 0.01 | 0.08 | 0.07 | 18.16 | 9.46 |

TABLE 3
Surface Roughness

Surface Roughness

| Form # | Pre-shear | Post-shear |
|---|---|---|
| Form 1 | 1.66 | 2.4 |
| Form 3 | 1.64 | 9.44 |
| Form 4 | 18.16 | 9.46 |

TABLE 4
Polishing Removal Rate (μm/min)

Polishing Removal
Rate(um/min)

| Form # | Pre-shear | Post-shear |
|---|---|---|
| Form 1 | 0.23 | 0.18 |
| Form 3 | 0.23 | 0.09 |
| Form 4 | 0.08 | 0.07 |

Formulation 1 showed no problems with hard packing (HP), dispersion (DD), removal rate (RR), and settling/suspension (Su). The concentration of all components was determined to be important for providing optimal shear stability, suspension characteristics, and the prevention of hard settling. Formulation 1 provided the best overall polishing performance.

Formulations 2, 3, and 4 were prepared to explore the concentration dependence of the first and second viscosity modifying agents and the pH adjusting agent. As can be seen by the presented data, the performance of the polishing compositions depends upon the concentrations of each component. If the concentration of each component is too high or too low, the polishing compositions show decreased performance. In an embodiment, the preferred wt % range of hydroxyethyl cellulose was from about 2 to about 3 wt %, for polyacrylic acid was from about 0.08 to about 0.2 wt %, and for diisopropanolamine was about 0.01 to about 0.025 wt %. In a further embodiment, the preferred wt % ratio of hydroxyethyl cellulose to polyacrylic acid was from about 25:1 to about 40:1. The interdependence of the component concentration was also a surprising and unexpected effect.

Formulation 4 was prepared with a higher concentration of hydroxyethyl cellulose and showed that as the concentration of hydroxyethyl cellulose increased, so did the starting viscosity, which provided protection against shear sensitivity. However, this formulation caused the removal rate to fail as it dropped to nearly zero. Thus, this high concentration of hydroxyethyl cellulose is too high to be used in a formulation for polishing SiC with a diamond abrasive, even though the polishing composition showed beneficial properties in low sensitivity to shear, hard packing and settling rate.

Formulations 5, 6, and 7 are abrasive-containing polishing compositions which contain diamond only, polyacrylic acid and diamond, and hydroxyethyl cellulose and diamond, respectively. In these three formulations, there is at least one failure in the performance. For example, Formulation 7, comprising only hydroxyethyl cellulose and diamond, was a very sticky formulation that was not suitable for resuspension of the abrasive following use.

Formulation 8 shows that without all three additives (and specifically without hydroxyethyl cellulose), there is a large drop in viscosity when shear is applied.

Additional comparator formulations were prepared. In some instances, they were prepared without hydroxyethyl cellulose. All formulations failed for shear resistance; that is, they dropped below 30 cP after being exposed to shear. The importance of hydroxyethyl cellulose was a surprising and unexpected result. Some formulations were prepared as vehicles only, thus not comprising an abrasive, and it was determined that the shear sensitivity of the vehicle is not affected by the presence of the diamonds.

An additional formulation was prepared with a low concentration of hydroxyethyl cellulose. The starting viscosity of this formulation is too low to suspend the abrasive particles and therefore cannot be used as a viable polishing composition.

A more concentrated version of Formulation 1 was prepared. The suspension, settling and shear resistance were all very good, with an overall increase in starting and final viscosity (as there is a limited drop in viscosity from starting to final). However, it is possible that the high concentration of hydroxyethyl cellulose could lead to a lower RR on a SiC surface. Specifically, it has been observed that there can be low to no removal rate when the concentration of hydroxyethyl cellulose and viscosity are too high.

In sum, it has been demonstrated that in the absence of all three chemical additives, the polishing vehicle and polishing composition will fail at least one test. However, when the correct concentration of all three chemical additives is present, both the polishing vehicle and polishing composition are resistant to shear and function as useable polishing vehicles and compositions.

It will be apparent to those skilled in the art that various modifications and variations can be made in the present invention without departing from the scope or spirit of the invention. Other aspects of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A polishing composition comprising a first viscosity modifying agent, a second viscosity modifying agent, a pH adjusting agent, an abrasive, and water, wherein
the first viscosity modifying agent comprises a cellulose derivative or a polysaccharide;
the second viscosity modifying agent comprises an anionic polymer;
the pH adjusting agent comprises an inorganic or amine base; and
the abrasive has an average particle size of about 50 nm or more.

2. The polishing composition of claim 1, wherein the first viscosity modifying agent is a cellulose derivative selected from the group consisting of hydroxypropylmethylcellulose (HPMC), carboxymethylcellulose (CMC), ethylcellulose, methylcellulose, hydroxyethyl cellulose, ethylhydroxyethyl cellulose, hydroxypropyl cellulose (HPC), microcrystalline cellulose, starch, their salts, and combinations thereof.

3. The polishing composition of claim 2, wherein the first viscosity modifying agent is hydroxyethyl cellulose.

4. The polishing composition of claim 1, wherein the first viscosity modifying agent is a polysaccharide selected from the group consisting of xanthan gum, guar gum, locust bean gum, tragacanth gum, gum arabic, acacia gum, agar, sodium alginate, potassium alginate, their salts, and combinations thereof.

5. The polishing composition of claim 1, wherein the first viscosity modifying agent is present in an amount from about 0.5 wt % to about 5 wt %.

6. The polishing composition of claim 1, wherein the anionic polymer is selected from the group consisting of a polyacrylic acid, a polysulfonic acid, and salts thereof.

7. The polishing composition of claim 6, wherein the anionic polymer is a polyacrylic acid or a salt thereof.

8. The polishing composition of claim 7, wherein the weight average molecular weight of the polyacrylic acid is from about 20 kDa to about 400 kDa.

9. The polishing composition of claim 1, wherein the anionic polymer is present in an amount from about 0.05 wt % to about 1 wt %.

10. The polishing composition of claim 1, wherein the base is an amine base selected from the group consisting of trimethylamine and diisopropanolamine.

11. The polishing composition of claim 1, wherein the base is an inorganic base selected from the group consisting of KOH and NaOH.

12. The polishing composition of claim 1, wherein the pH of the polishing composition is from about 3 to about 9.

13. The polishing composition of claim 1, wherein the abrasive is selected from the group consisting of silica particles, alumina particles, cerium oxide particles, chromium oxide particles, titanium dioxide particles, zirconium oxide particles, magnesium oxide particles, manganese dioxide particles, zinc oxide particles, red iron oxide particles, silicon nitride particles, boron nitride particles, silicon carbide particles, boron carbide particles, diamond particles, calcium carbonate, barium carbonate, and combinations thereof.

14. The polishing composition of claim 1, wherein the polishing composition has about a 25% difference in viscosity between the pre-shear and post-shear measurements.

15. A method of preparing the polishing composition of claim 1, the method comprising the steps of mixing the first viscosity modifying agent, the second viscosity modifying agent, the pH adjusting agent, the abrasive, and water.

16. A method for polishing a substrate, the method comprising the steps of:
1) preparing the polishing composition of claims 1; and
2) polishing the substrate with the polishing composition.

17. The method of claim 16, wherein the substrate is a semiconductor.

18. The polishing composition of claim 1, wherein the viscosity of the composition is 50 to 500 cP in the working vehicle formulation and 50-10,000 cP in the concentrate.
